(19) United States
(12) Patent Application Publication
(10) Pub. No.: US 2026/0096323 A1
(43) Pub. Date: Apr. 2, 2026

(54) DISPLAY DEVICE

(71) Applicant: LG Display Co., Ltd., Seoul (KR)

(72) Inventor: Jongmoo HA, Gimpo-si (KR)

(21) Appl. No.: 19/346,064

(22) Filed: Sep. 30, 2025

(30) Foreign Application Priority Data
Sep. 30, 2024 (KR) 10-2024-0132762

(51) Int. Cl. H10K 59/131

(52) U.S. Cl. CPC H10K 59/131

(57) ABSTRACT

A display device includes a substrate including a link area on one side of a display area; data link lines disposed on the link area and connected to data lines disposed on the display area; and a first power supply line and a second power supply line disposed on the link area and intersecting the data link lines, wherein the first power supply line and the second power supply line are spaced apart from each other, wherein in a plan view of the display device, each of the data link lines is partially disposed in and extends along an area between the first power supply line and the second power supply line, wherein in the plan view, each of the data link lines has at least one stepped portion with a plurality of bends in the area between the first power supply line and the second power supply line.

### CROSS-REFERENCE TO RELATED APPLICATION

Pursuant to 35 U.S.C. § 119(a), this application claims the benefit of an earlier filing date and right of priority to Korean Patent Application No. 10-2024-0132762 filed on Sep. 30, 2024 in the Korean Intellectual Property Office, the contents of which in its entirety are herein incorporated by reference.

### TECHNICAL FIELD

The present disclosure relates to a display device.

### BACKGROUND

Display devices are applied to various electronic devices such as TV, mobile phones, laptops, and tablets.

The display device can be implemented, for example, with an organic light-emitting display (OLED) that emits light by itself or a liquid crystal display (LCD) that requires a separate light source.

A bezel area of the display device is often visible to the user and can be a factor that degrades aesthetics and visibility. Recently, display devices have been developed with a narrow bezel model and reduced bezel area in which an image of a display device is not displayed.

### SUMMARY

A display device according to one implementation of the present disclosure includes: a substrate including a display area and a link area disposed on one side of the display area; a plurality of data link lines disposed on the link area and connected to a plurality of data lines disposed on the display area; and a first power supply line and a second power supply line disposed on the link area and intersecting the plurality of data link lines, wherein the first power supply line and the second power supply line are spaced apart from each other, wherein in a plan view of the display device, each of the plurality of data link lines is partially disposed in and extends along an area between the first power supply line and the second power supply line, wherein in the plan view, each of the plurality of data link lines includes at least one stepped portion with a plurality of bends in the area between the first power supply line and the second power supply line.

A display device according to one implementation of the present disclosure includes: a substrate including a display area and a link area disposed on one side of the display area; first, second, and third data link lines disposed on the link area and respectively positioned in different layers, wherein the first, second, and third data link lines do not overlap each other in a direction perpendicular to an upper surface of the substrate, wherein a vertical level of each of the third data link lines is higher than a vertical level of each of the first and second data link lines; an interlayer insulating layer covering the third data link lines; and a first power supply line and a second power supply line disposed on the link area and on the interlayer insulating layer and intersecting the first to third data link lines, wherein the first power supply line and the second power supply line are spaced apart from each other, wherein each of the first to third data link lines has at least one stepped portion with a plurality of bends in an area between the first power supply line and the second power supply line, wherein the interlayer insulating layer includes first concave portions, wherein each of the first concave portions is formed between adjacent ones of the stepped portions of the second data link lines and the third data link lines in the area between the first power supply line and the second power supply line, wherein the first concave portions are arranged along at least one line.

According to implementations of the present disclosure, the plurality of data link lines may have at least one stepped portion in the area between the first power supply line and the second power supply line, and the spacing between the stepped portions of the plurality of data link lines may be greater than the spacing between the straight portions of the plurality of data link lines, so that the residual film of the metal material may be easily removed from the concave portions of the interlayer insulating layer positioned between the stepped portions of the plurality of data link lines.

According to implementations of the present disclosure, a short-circuit between the first power supply line and the second power supply line due to a residual film of a metal material between the plurality of data link lines may be prevented from occurring.

In addition, the spacing between the first power supply line and the second power supply line may be narrowed in the non-display area of the display panel, such that the width of the bezel area of the display device may be reduced.

In addition, according to implementations of the present disclosure, a defect rate of the display device due to the short-circuit between the first and second power supply lines of the display panel may be reduced, so that production energy required for production of the display device may be reduced and greenhouse gas emission may be reduced.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF DRAWINGS

FIG. 1 is a plan view of an example of a display device according to an implementation of the present disclosure.

FIG. 2 is a cross-sectional view of an example of the display device taken along a line II-II of FIG. 1.

FIG. 3 is an enlarged view illustrating an example of an area A of FIG. 1.

FIG. 4 is an enlarged view illustrating an example of an area B1 of FIG. 3.

FIG. 5 is a cross-sectional view of an example of the display device taken along a line V-V of FIG. 4.

FIG. 6 is an enlarged view illustrating an example of an area B2 of FIG. 3.

FIG. 7 is a cross-sectional view of an example of the display device taken along a line VII-VII of FIG. 1.

### DETAILED DESCRIPTIONS

In some scenarios, a bezel area of a display device can be reduced by narrowing a spacing between data link lines that are disposed in the non-display area of the display panel. Furthermore, the data link lines can be divided into several groups which are disposed in several layers.

Power supply lines can also be disposed in the non-display area of the display panel. The power supply lines can supply various voltages to the display area of the display panel, for example, a high-potential voltage supply line and a low-potential voltage supply line. In this regard, the power supply lines may intersect the data link lines. For example, the power supply lines may be located on an interlayer insulating layer covering the uppermost data link lines. Due to the data link lines spaced from each other by a small spacing, concave portions having a narrow width may be formed in the interlayer insulating layer.

In the process of forming the power supply lines, a metal material used for forming the power supply lines may remain as a residual film in the concave portions of the interlayer insulating layer. Such a residual film of the metal material may cause a short-circuit between the power supply lines.

The smaller the spacing between the power supply lines, the more advantageous it can be to reduce the bezel area of the display device. However, as the spacing between the power supply lines is smaller, the probability increases that a short-circuit can occur between the power supply lines due to a residual film of a metal material remaining in the areas between the data link lines. For this reason, it can be difficult to narrow the spacing between the power supply lines.

Implementations of the present disclosure can provide a display device in which a residual film may be removed in areas between the data link lines, and a short-circuit between the power supply lines may be prevented from occurring.

Implementations of the present disclosure can provide a display device in which a residual film of a metal material may be removed in an area between data link lines disposed between power supply lines.

As such, various technical benefits can be achieved, such as providing a display device capable of preventing a short-circuit between power supply lines.

Purposes according to the present disclosure are not limited to the above-mentioned purpose. Other purposes and advantages according to the present disclosure that are not mentioned may be understood based on following descriptions, and may be more clearly understood based on implementations according to the present disclosure. Further, it will be easily understood that the purposes and advantages according to the present disclosure may be realized using means shown in the claims or combinations thereof.

Advantages and features of the present disclosure, and a method of achieving the advantages and features will become apparent with reference to implementations described below in detail together with the accompanying drawings. However, the present disclosure is not limited to the implementations as disclosed under, but may be implemented in various different forms. Thus, these implementations are set forth only to make the present disclosure complete, and to entirely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various implementations are illustrated and described further below. It will be understood that the description herein is not intended to limit the claims to the specific implementations described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating implementations of the present disclosure are illustrative, and the present disclosure is not limited thereto. The terminology used herein is directed to the purpose of describing particular implementations only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify an entirety of the list of elements and may not modify the individual elements of the list.

In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when a first element or layer is referred to as being “connected to”, or “coupled to” a second element or layer, the first element may be directly connected to or coupled to the second element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present therebetween.

Further, as used herein, when a layer, film, area, plate, or the like is disposed “on” or “on a top” of another layer, film, area, plate, or the like, the former may directly contact the latter or still another layer, film, area, plate, or the like may be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former may directly contact the latter or still another layer, film, area, plate, or the like may be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is indicated. When a certain implementation may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

When an implementation may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various implementations of the present disclosure may be partially or entirely combined with each other, and may be technically associated with each other or operate with each other. The implementations may be implemented independently of each other and may be implemented together in an association relationship.

In interpreting a numerical value, the value is interpreted as including an error range unless there is separate explicit description thereof. Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “implementations,” “examples,” “aspects, etc. should not be construed such that any aspect or design as described is superior to or advantageous over other aspects or designs. Further, the term ‘or’ means ‘inclusive or’ rather than ‘exclusive or’. That is, unless otherwise stated or clear from the context, the expression that ‘x uses a or b’ means one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating implementations. Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used. Throughout the present disclosure, “A and/or B” means A, B, or A and B, unless otherwise specified, and “C to D” means C inclusive to D inclusive unless otherwise specified.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally.

Hereinafter, various implementations of the present disclosure will be described in detail with reference to the accompanying drawings.

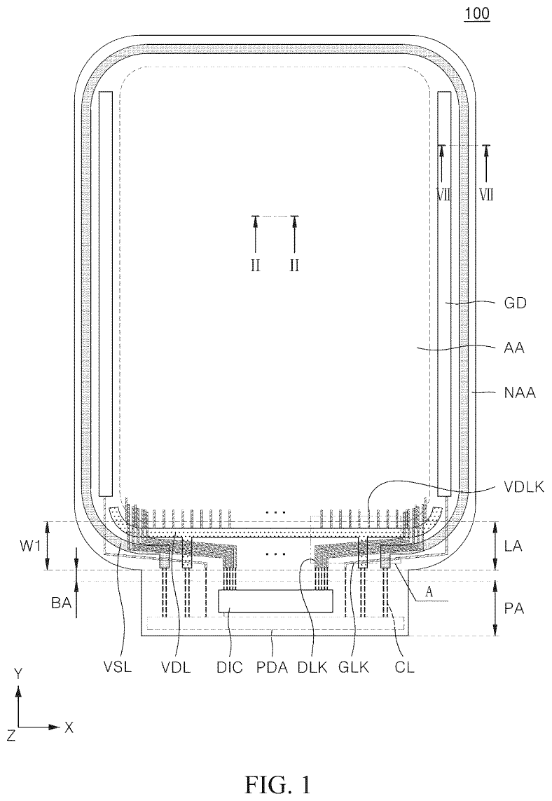

FIG. 1 is a plan view of an example of a display device according to an implementation of the present disclosure.

Referring to FIG. 1, a display device according to an implementation of the present disclosure may include a display panel 100, a data driver DIC, a flexible printed circuit board, a timing controller, a power supply, etc.

The display panel 100 includes a substrate on which a display area AA and a non-display area NAA are defined. The display area AA is an area in which an image is implemented. The non-display area NAA is an area in which an image outside the display area AA is not implemented.

The display area AA is an area in which a plurality of pixels are arranged. Each pixel may include a plurality of sub-pixels. The non-display area NAA is an area in which a gate driver GD, link lines GLK and DLK, power supply lines VDL and VSL, a connection line CL, etc. are disposed.

The display area AA includes a plurality of data lines and a plurality of gate lines intersecting each other. The plurality of data lines may extend, for example, in the Y-axis direction, and the plurality of gate lines may extend, for example, in the X-axis direction. The plurality of data lines transmit a data signal generated by the data driver DIC to the plurality of pixels, and the plurality of gate lines transmit a gate signal generated by the gate driver GD to the plurality of pixels. The display area AA may further include a plurality of first power lines extending in a direction parallel to the plurality of data lines. The plurality of first power lines PL1 may transmit a first voltage as a high potential voltage to the plurality of pixels.

The non-display area NAA may be disposed to surround an upper side, a lower side, a left side, and a right side of the display area AA. A portion of the non-display area NA located on the lower side of the display area AA includes a pad area PA to which the data driver DIC and a flexible printed circuit board (not shown) are bonded, and a link area LA and a bendable area BA defined between the display area AA and the pad area PA.

The data driver DIC and the flexible printed circuit board may be bonded to the pad area PA via an anisotropic conductive film. The flexible printed circuit board may be bonded to a pad array area PDA disposed at an end of the pad area PA. A plurality of pads may be disposed in the pad array area PDA. A timing controller and a power supply may be mounted on the flexible printed circuit board.

A portion of the non-display area NAA of the display panel 100 may be bent at a predetermined curvature. A bendable area of the non-display area NAA of the display panel 100 may be defined as the bendable area BA.

As the display panel 100 is bent, the pad area PA of the non-display area NAA may be positioned to overlap the display area AA while being disposed under the display area AA. Accordingly, a bezel area of a lower side of the display device recognized from a viewer in front of the display device may be reduced. In this case, a width of the bezel area of the lower side of the display device may be determined based on a width W1 of the link area LA.

For example, the gate driver GD may be disposed in the non-display area NAA and located on each of the left and right sides of the display area AA. The gate driver GD may be directly disposed on the substrate of the display panel 100 in a gate driver in panel (GIP) manner.

In the portion of the non-display area NAA located on the lower sider of the display area AA, a first power supply line VDL for supplying a first voltage Vdd as a high potential voltage to the first power lines of the display area AA and a second power supply line VSL for supplying a second voltage Vss as a low potential voltage to cathode electrodes of light-emitting elements disposed in the display area AA may be disposed. The first power supply line VDL and the second power supply line VSL may be spaced apart from each other.

A plurality of data link lines DLK for transmitting a data signal to the plurality of data lines and a plurality of gate link lines GLK for transmitting a gate signal to the gate driver GD may be disposed in the portion of the non-display area NAA located on the lower side of the display area AA.

At least some of the plurality of data link lines DLK may intersect the first power supply line VDL and the second power supply line VSL. At least some of the plurality of data link lines DLK may extend across an area between the first power supply line VDL and the second power supply line VSL. The plurality of data link lines DLK may be connected to and disposed between the data driver DIC and the plurality of data lines, and may be bent a plurality of times. Each of the plurality of data link lines DLK may include, for example, a section obliquely extending in a direction defining an acute angle with respect to the first direction (X-axis direction) in the link area LA. In an implementation, each of the plurality of data link lines DLK may include, for example, a section extending in a direction parallel to the first direction (X-axis direction) in the link area LA. The plurality of data link lines DLK may be connected to the data driver DIC via the connection line CL extending across the bendable area BA and the pad area PA.

At least some of the plurality of gate link lines GLK may intersect the first power supply line VDL and the second power supply line VSL. The plurality of gate link lines GLK may be connected to the connection line CL extending across the bendable area BA and the pad area PA. The plurality of gate link lines GLK may be connected to the pad array area PDA of the pad area PA via the connection line CL.

The first power supply line VDL may be disposed in the link area LA of the non-display area NAA. The first power supply line VDL may be connected to the connection line CL extending across the bendable area BA and the pad area PA. The first power supply line VDL may intersect the plurality of data link lines DLK in the link area LA. The first power supply line VDL may include a first extension portion extending in the first direction (e.g., X-axis direction) and a second extension portion extending from the first extension portion in the second direction (e.g., Y-axis direction). The second extension portion of the first power supply line VDL may be connected to the pad array area PDA of the pad area PA via the connection line CL. The first power supply line VDL may be connected to the first power lines of the display area AA via the power link lines VDLK.

The second power supply line VSL may be disposed to surround the display area AA. A portion of the second power supply line VSL may be disposed in the link area LA. The second power supply line VSL may be connected to the connection line CL extending across the bendable area BA and the pad area PA. The second power supply line VSL may intersect the plurality of data link lines DLK in the link area LA. The cathode electrode of the light-emitting element disposed in the display area AA may be electrically connected to the second power supply line VSL in the non-display area NAA. A portion of the second power supply line VSL disposed on the lower side of the display area AA may include a first extension portion extending in the first direction (e.g., X-axis direction) and a second extension portion extending from the first extension portion in the second direction (e.g., Y-axis direction). The first extension of the second power supply line VSL may be disposed in the link area LA. The second extension portion of the second power supply line VSL may be connected to the pad array area PDA of the pad area PA via the connection line CL.

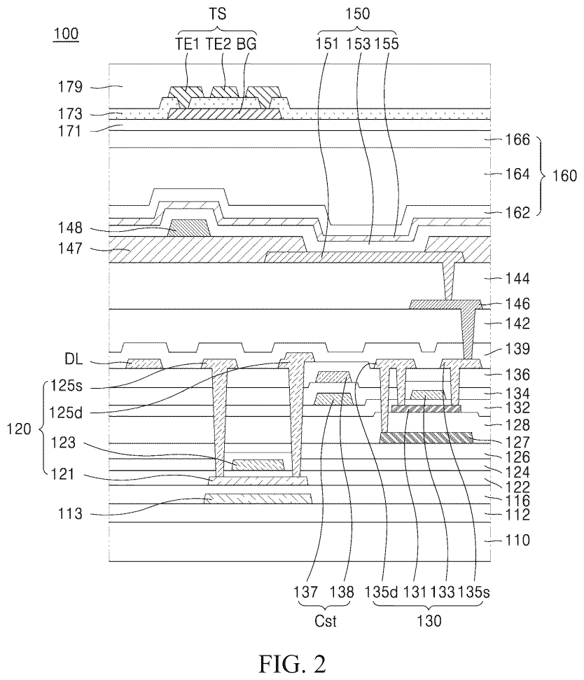

FIG. 2 is a cross-sectional view of an example of the display device taken along a line II-II of FIG. 1. FIG. 2 schematically illustrates a sub-pixel of a display device.

Referring to FIG. 2, the display device may include a substrate 110a, and a plurality of thin-film transistors 120 and 130, one capacitor Cst, and a light-emitting element 150 disposed on the substrate 110. The plurality of thin-film transistors 120 and 130 may include a first thin-film transistor 120 including a polycrystalline semiconductor material and a second thin-film transistor 130 including an oxide semiconductor material.

One sub-pixel includes the light-emitting element 150 and a pixel driving circuit for applying a driving current to the light-emitting element 150. The pixel driving circuit is disposed on the substrate 110, and the light-emitting element 150 is disposed on the pixel driving circuit. The pixel driving circuit may include a driving thin-film transistor, one or more switching thin-film transistors, and a capacitor. Each of the first and second thin-film transistors 120 and 130 may act as, for example, the switching thin-film transistor.

The substrate 110 may be made of a flexible material so as to be bendable. For example, the substrate 110 may be made of an organic insulating material such as polyimide. The substrate 110 may be implemented as, for example, a multi-layers stack in which organic insulating material layers and inorganic insulating material layers are alternately stacked on each other. For example, the substrate 110 may be formed by alternately stacking organic insulating material layers made of, such as, polyimide and inorganic insulating material layers, made of, such as silicon oxide (SiOx) on each other. For example, the substrate 110 may have a three-layer structure in which a silicon oxide layer is disposed between two polyimide layers.

A first lower buffer layer 112 and a second lower buffer layer 116 are formed on the substrate 110. Each of the first and second lower buffer layers 112 and 116 may be embodied as a single layer or a multilayer stack made of an inorganic insulating material such as silicon oxide (SiOx), silicon nitride (SiNx), or the like to block moisture or oxygen that may be input in a permeated manner from the outside. The first light-shielding layer 113 may be disposed between the first lower buffer layer 112 and the second lower buffer layer 116.

The first thin-film transistor 120 may be disposed on the second lower buffer layer 116. The first thin-film transistor 120 includes a first active layer 121 made of a polycrystalline semiconductor material, a first gate electrode 123 overlapping a channel area of the first active layer 121, a first source electrode 125s connected to a source area of the first active layer 121, and a first drain electrode 125d connected to a drain area of the first active layer 121.

The first active layer 121 may be disposed on the second lower buffer layer 116. A first gate insulating layer 122 is disposed between the first gate electrode 123 and the first active layer 121. The first gate insulating layer 122 may cover the first active layer 121 and may be disposed on the second lower buffer layer 116. The first gate insulating layer 122 may be embodied as a single layer or a multilayer stack made of an inorganic insulating material such as silicon oxide (SiOx) or silicon nitride (SiNx).

Between the first lower buffer layer 112 and the second lower buffer layer 116, a first light-shielding layer 113 is disposed to overlap the first active layer 121, and prevent the light from being incident on the first active layer 121, thereby securing reliability of the first thin-film transistor 120. The first light-shielding layer 113 may be made of a metal material. The first light-shielding layer 113 may be electrically connected to the first gate electrode 123 to form a dual gate. For example, the first light-shielding layer 113 may be embodied as a single layer or a multilayer stack made of one of molybdenum (Mo), aluminum (Al), chromium (Cr), gold (Au), titanium (Ti), nickel (Ni), neodymium (Nd), and copper (Cu), or an alloy thereof. However, implementations of the present disclosure are not limited thereto.

A first interlayer insulating layer 124 and a second interlayer insulating layer 126 may be disposed on the first gate electrode 123. The first interlayer insulating layer 124 and the second interlayer insulating layer 126 may be embodied as a single layer or a multilayer stack made of an inorganic insulating material such as silicon oxide (SiOx) or silicon nitride (SiNx).

The second light-shielding layer 127 may be disposed on the second interlayer insulating layer 126. The second light-shielding layer 127 is made of a metal material. For example, the second light-shielding layer 127 may be embodied as a single layer or a multilayer stack made of one of molybdenum (Mo), aluminum (Al), chromium (Cr), gold (Au), titanium (Ti), nickel (Ni), neodymium (Nd), and copper (Cu), or an alloy thereof. However, implementations of the present disclosure are not limited thereto.

An upper buffer layer 128 may be disposed on the second light-shielding layer 127. The second thin-film transistor 130 may be disposed on the upper buffer layer 128. The second thin-film transistor 130 includes a second active layer 131 made of an oxide semiconductor material, a second gate electrode 133 overlapping a channel area of the second active layer 131, a second source electrode 135s connected to a source area of the second active layer 131, and a second drain electrode 135d connected to a drain area of the second active layer 131. The upper buffer layer 128 spaces the second active layer 131 made of an oxide semiconductor material from the first active layer 121 made of a polycrystalline semiconductor material from each other, and provides a basis for forming the second active layer 131. The upper buffer layer 128 may be embodied as a single layer or a multilayer stack made of an inorganic insulating material such as silicon oxide (SiOx) or silicon nitride (SiNx).

The second active layer 131 may be disposed on the upper buffer layer 128. A second gate insulating layer 132 is disposed between the second gate electrode 133 and the second active layer 131. The second gate insulating layer 132 may cover the second active layer 131 and may be disposed on the upper buffer layer 128. The second gate insulating layer 132 may be embodied as a single layer or a multilayer stack made of an inorganic insulating material such as silicon oxide (SiOx) or silicon nitride (SiNx).

A lower electrode 137 and of the capacitor Cst and the second gate electrode 133 and may be disposed on the second gate insulating layer 132. The lower electrode 137 may be made of the same material as that of the second gate electrode 133. The lower electrode 137 and the second gate electrode 133 are made of a metal material. For example, each of the lower electrode 137 and the second gate electrode 133 may be embodied as a single layer or a multilayer stack made of one of molybdenum (Mo), aluminum (Al), chromium (Cr), gold (Au), titanium (Ti), nickel (Ni), neodymium (Nd), and copper (Cu), or an alloy thereof. However, implementations of the present disclosure are not limited thereto.

A second light-shielding layer 129 may be disposed to overlap the second active layer 131, and may prevent the light from being incident on the second active layer 131, thereby securing reliability of the second thin-film transistor 130. The second light-shielding layer 129 may be electrically connected to the second drain electrode 135d.

A third interlayer insulating layer 134 covering the lower electrode 137 and the second gate electrode 133 may be disposed on the second gate insulating layer 132. The third interlayer insulating layer 134 may be embodied as a single layer or a multilayer stack made of an inorganic insulating material such as silicon oxide (SiOx) or silicon nitride (SiNx).

An upper electrode 138 of the capacitor Cst may be disposed on the third interlayer insulating layer 134 so as to overlap the lower electrode 137. A fourth interlayer insulating layer 136 may be disposed on the third interlayer insulating layer 134 so as to cover the upper electrode 138. The upper electrode 138 is made of a metal material. For example, the upper electrode 138 may be embodied as a single layer or a multilayer stack made of one of molybdenum (Mo), aluminum (Al), chromium (Cr), gold (Au), titanium (Ti), nickel (Ni), neodymium (Nd), and copper (Cu) or an alloy thereof. However, implementations of the present disclosure are not limited thereto. The fourth interlayer insulating layer 136 may be embodied as a single layer or a multilayer stack made of an inorganic insulating material such as silicon oxide (SiOx) or silicon nitride (SiNx).

The first source electrode 125s, the first drain electrode 125d, the second source electrode 135s, and the second drain electrode 135d may be disposed on the fourth interlayer insulating layer 136. The first source electrode 125s, the first drain electrode 125d, the second source electrode 135s, and the second drain electrode 135d may be made of the same material and may be simultaneously formed on the fourth interlayer insulating layer 136. The first source electrode 125s and the first drain electrode 125d may be connected to the source area and the drain area of the first active layer 121, respectively, via respective through-holes extending through the third and fourth interlayer insulating layers 134 and 136, the second gate insulating layer 132, the upper buffer layer 128, the first and second interlayer insulating layers 124 and 126, and the first gate insulating layer 122. The second source electrode 135s and the second drain electrode 135d may be connected to the source area and the drain area of the second active layer 131, respectively, via respective through-holes extending through the third and fourth interlayer insulating layers 134 and 136 and the second gate insulating layer 132. Each of the first source electrode 125s, the first drain electrode 125d, the second source electrode 135s, and the second drain electrode 135d may be embodied as a single layer or a multilayer stack made of one of molybdenum (Mo), aluminum (Al), chromium (Cr), gold (Au), titanium (Ti), nickel (Ni), neodymium (Nd), and copper (Cu), or an alloy thereof. However, implementations of the present disclosure are not limited thereto. Each of the first source electrode 125s, the first drain electrode 125d, the second source electrode 135s, and the second drain electrode 135d may have a multi-layered structure of a titanium (Ti) layer/an aluminum (Al) layer/a titanium (Ti) layer.

The data line DL may be disposed on the fourth interlayer insulating layer 136. The data line DL may be embodied as a single layer or a multilayer stack made of one of molybdenum (Mo), aluminum (Al), chromium (Cr), gold (Au), titanium (Ti), nickel (Ni), neodymium (Nd), and copper (Cu) or an alloy thereof. However, implementations of the present disclosure are not limited thereto. For example, the data line DL may have a multilayer structure of a titanium (Ti) layer/an aluminum (Al) layer/a titanium (Ti) layer.

A passivation layer 139 covering the first source electrode 125s, the first drain electrode 125d, the second source electrode 135s, the second drain electrode 135d, and the data line DL may be disposed on the fourth interlayer insulating layer 136.

In one example, a first planarization layer 142 and a second planarization layer 144 may be sequentially disposed on the passivation layer 139 to planarize a step due to the pixel driving circuit. Each of the first planarization layer 142 and the second planarization layer 144 may be made of an organic insulating material such as polyimide or acrylic resin.

In addition, the light-emitting element 150 may be disposed on the second planarization layer 144.

The light-emitting element 150 includes an anode electrode 151, a cathode electrode 155, and a light-emitting layer 153 disposed between the anode electrode 151 and the cathode electrode 155.

The light-emitting element 150 is electrically connected to the pixel driving circuit via an intermediate electrode 146 disposed on the first planarization layer 142. For example, the anode electrode 151 of the light-emitting element 150 may be connected to the second drain electrode 135d or the second source electrode 135s of the second thin-film transistor 130 via the intermediate electrode 146.

The anode electrode 151 may be connected to the intermediate electrode 146 via a contact hole extending through the second planarization layer 144. For example, the intermediate electrode 146 may be connected to the second drain electrode 135d via a contact hole extending through the first planarization layer 142.

The intermediate electrode 146 may be embodied as a single layer or a multilayer stack made of one of molybdenum (Mo), aluminum (Al), chromium (Cr), gold (Au), titanium (Ti), nickel (Ni), neodymium (Nd), and copper (Cu) or an alloy thereof. However, implementations of the present disclosure are not limited thereto. For example, the intermediate electrode 146 may have a multilayer structure of a titanium (Ti) layer/an aluminum (Al) layer/a titanium (Ti) layer.

The anode electrode 151 may be formed in a multilayer structure including a transparent conductive film and an opaque conductive film having high reflection efficiency. The transparent conductive film may be made of a material having a relatively high work function value, such as indium-tin-oxide (ITO) or indium-zinc-oxide (IZO), and the opaque conductive film may be made of a single-layer or multi-layer structure including aluminum (Al), silver (Ag), copper (Cu), lead (Pb), molybdenum (Mo), titanium (Ti), or an alloy thereof. For example, the anode electrode 151 may be formed in a structure in which a transparent conductive film, an opaque conductive film, and a transparent conductive film are sequentially stacked, or may be formed in a structure in which a transparent conductive film and an opaque conductive film are sequentially stacked.

The light-emitting layer 153 may include a hole injection layer, a hole transport layer, an organic light-emitting layer, an electron transport layer, and an electron injection layer disposed on the anode electrode 151.

A bank layer 147 may be disposed on the second planarization layer 144. The bank layer 147 may act as a pixel defining layer exposing a central area of each anode electrode 151. The bank layer 147 may be made of an organic insulating material. The bank layer 147 may include, for example, one of photosensitive polyimide, photoacryl, and benzocyclobutene (BCB). The bank layer 147 may be made of an opaque material to prevent optical interference between adjacent pixels. In this case, the bank layer 147 includes a light-shielding material made of at least one of a color pigment, organic black, and carbon.

A spacer 148 may be further disposed on the bank layer 147. A fine metal mask as a deposition mask may be used to form the light-emitting layer 153. In order to prevent damage to the bank layer 147 and the anode electrode 151 that may occur due to contact thereof with the deposition mask by maintaining a predetermined spacing between the bank layer 147 and the deposition mask, the spacer 148 may be disposed on the bank layer 147.

The spacer 148 may be made of the same material as that of the bank layer 147. The spacer 148 and the bank layer 147 may be formed simultaneously in a single process. However, implementations of the present disclosure are not limited thereto. The spacer 148 may be made of a material different from that of the bank layer 147 and may be formed on the bank layer 147 through a separate process from a formation process of the bank layer. The spacer 148 may be made of an organic insulating material. The spacer 148 may include one of photosensitive polyimide, photoacryl, and benzocyclobutene (BCB).

The cathode electrode 155 may be formed integrally and may be disposed across an entirety of the display area AA. In a top emission type organic light-emitting display device, the cathode electrode 155 may be made of a transparent conductive layer such as indium-tin-oxide (ITO) or indium-zinc-oxide (IZO). The cathode electrode 155 may be electrically connected to the second power supply line VSL (see FIG. 1) in the non-display area NAA.

An encapsulation layer 160 for suppressing moisture penetration may be further disposed on the cathode electrode 145. The encapsulation layer 160 may include a first inorganic encapsulation layer 162, an organic encapsulation layer 164, and a second inorganic encapsulation layer 166, which are sequentially stacked.

Each of the first inorganic encapsulation layer 162 and the second inorganic encapsulation layer 166 of the encapsulation layer 160 may be made of an inorganic insulating material such as silicon oxide (SiOx) or silicon nitride (SiNx). The organic encapsulation layer 164 of the encapsulation layer 160 may be made of an organic insulating material such as acryl resin, epoxy resin, phenolic resin, polyamide resin, and polyimide resin.

The touch sensor layer TS may be disposed on the encapsulation layer 160. The touch sensor layer TS may include a first touch electrode TE1, a bridge electrode BG, and a second touch electrode TE2. The first touch electrode TE1 and the second touch electrode TE2 may have a mesh structure.

A touch buffer layer 171 may be disposed on the encapsulation layer 160. The touch buffer layer 171 may prevent the encapsulation layer 160 and the light-emitting element 150 from being damaged by a process of forming the bridge electrode BG and the touch electrodes TE1 and TE2. For example, an upper surface of the encapsulation layer 160 may be covered with the touch buffer layer 171. For example, the touch buffer layer 171 may extend to the non-display area NAA. The touch buffer layer 171 may include an insulating material. For example, the touch buffer layer 171 may include an inorganic insulating material such as silicon oxide, silicon nitride, and silicon oxynitride.

The bridge electrode BG may be disposed on the touch buffer layer 171. In addition, a touch insulating layer 173 may be disposed on the bridge electrode BG. The touch insulating layer 173 may extend along the upper surface of the touch buffer layer 171. For example, the touch insulating layer 173 may extend to the non-display area NAA. For example, the touch insulating layer 173 may include an inorganic insulating material such as silicon oxide, silicon nitride, and silicon oxynitride.

The first touch electrode TE1 and the second touch electrode TE2 may be disposed on the touch insulating layer 173. The bridge electrode BG may electrically connect neighboring first touch electrodes TE1 to each other. The first touch electrodes TE1 may be connected to the bridge electrode BG via respective touch contact holes extending through the touch insulating layer 173.

Each of the first and second touch electrodes TE1 and TE2 and the bridge electrode BG may include a conductive material. For example, each of the first and second touch electrodes TE1 and TE2 and the bridge electrode BG may include a metal material such as aluminum (Al), chromium (Cr), copper (Cu), titanium (Ti), molybdenum (Mo), and tungsten (W). For example, each of the first and second touch electrodes TE1 and TE2 and the bridge electrode BG may have a multi-layered structure of a titanium (Ti) layer/an aluminum (Al) layer/a titanium (Ti) layer. For example, the first and second touch electrodes TE1 and TE2 and the bridge electrode BG may overlap the bank layer 147. Accordingly, light emitted from the light-emitting element 150 may not be blocked by the touch electrodes TE1 and TE2 and the bridge electrode BG.

A touch protection layer 179 may be disposed on the touch sensor layer TS. The touch protection layer 179 may prevent damage to the touch sensor layer TS due to external impact and moisture. The touch protection layer 179 may include an insulating material. For example, the touch protection layer 179 may include an organic insulating material. For example, the touch protection layer 179 may be made of a photosensitive acrylic-based or polyimide-based organic material. The touch protection layer 179 may extend to the non-display area NAA.

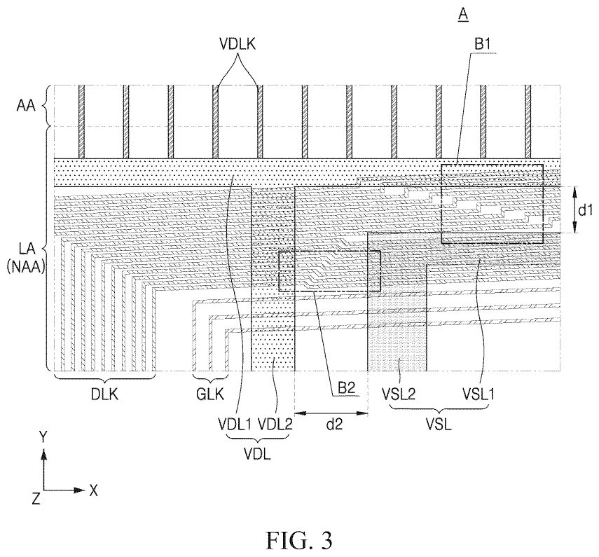

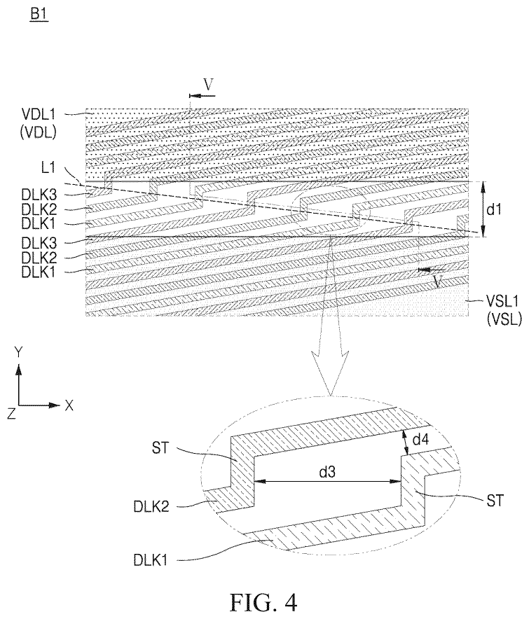

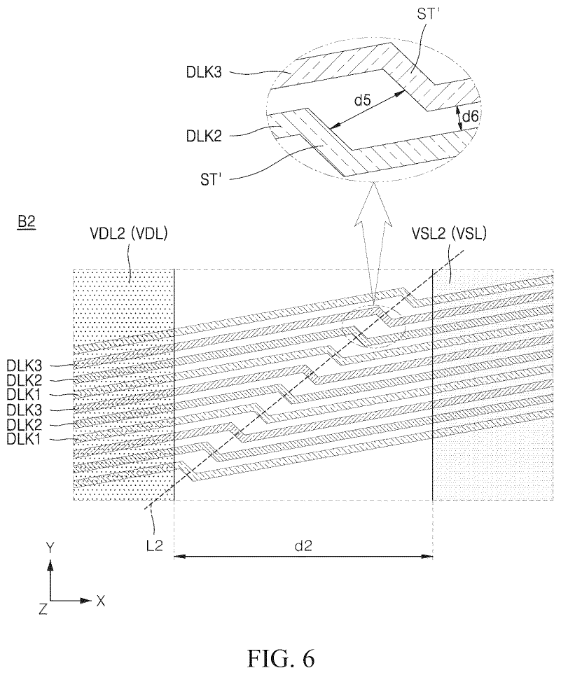

FIG. 3 is an enlarged view illustrating an area A of FIG. 1. FIG. 4 is an enlarged view illustrating an area B1 of FIG. 3. FIG. 6 is an enlarged view illustrating an area B2 of FIG. 3.

Referring to FIGS. 3, 4, and 6, in the link area LA of the non-display area NAA, the first power supply line VDL may include a first extension portion VDL1 extending in the first direction (e.g., the X-axis direction) and a second extension portion VDL2 extending from the first extension portion VDL1 in the second direction (e.g., the Y-axis direction). The first power supply line VDL may be connected to the first power lines of the display area AA via the power link lines VDLK. The first power supply line VDL may intersect the plurality of data link lines DLK in the link area LA. The first power supply line VDL may be located on the plurality of data link lines DLK, and the first power supply line VDL and the plurality of data link lines DLK may be electrically insulated from each other. The plurality of data link lines DLK may include first to third data link lines DLK1, DLK2, and DLK3. The first to third data link lines DLK1, DLK2, and DLK3 may be disposed in different layers on the substrate. The first to third data link lines DLK1, DLK2, and DLK3 may not overlap each other in a direction perpendicular to an upper surface of the substrate.

In the link area LA of the non-display area NAA, the second power supply line VSL may include a first extension portion VSL1 extending in the first direction (e.g., the X-axis direction) and a second extension portion VSL2 extending from the first extension portion VSL1 in the second direction (e.g., the Y-axis direction). The second power supply line VSL may intersect the plurality of data link lines DLK in the link area LA. The second power supply line VSL may be located on the plurality of data link lines DLK, and the second power supply line VSL and the plurality of data link lines DLK may be electrically insulated from each other.

In the link area LA of the non-display area NAA, the first power supply line VDL and the second power supply line VSL are disposed in the same layer and are spaced apart from each other. The first extension portion VDL1 of the first power supply line VDL and the first extension portion VSL1 of the second power supply line VSL may be spaced apart from each other by a first spacing d1, and the second extension portion VDL2 of the first power supply line VDL and the second extension portion VSL2 of the second power supply line VSL may be spaced apart from each other by a second spacing d2. The first spacing d1 between the first extension portion VDL1 of the first power supply line VDL and the first extension portion VSL1 of the second power supply line VSL may be smaller than the second spacing d2 between the second extension portion VDL2 of the first power supply line VDL and the second extension portion VSL2 of the second power supply line VSL.

At least some of the plurality of data link lines DLK may pass through an area between the first power supply line VDL and the second power supply line VSL. Each of the data link lines DLK passing through the area between the first power supply line VDL and the second power supply line VSL may be bent a plurality of times in the area between the first power supply line VDL and the second power supply line VSL so as to have at least one stepped portion ST and ST′. In an implementation, each of the data link lines DLK passing through the area between the first power supply line VDL and the second power supply line VSL may be bent twice in the area between the first power supply line VDL and the second power supply line VSL so as to have one stepped portion ST and ST′. In another implementation, each of the data link lines DLK passing through the area between the first power supply line VDL and the second power supply line VSL may be bent four times in the area between the first power supply line VDL and the second power supply line VSL so as to have two stepped portions. In this regard, the stepped portion means a portion between two bent portions.

The stepped portions ST and ST′ of the plurality of data link lines DLK may be arranged along at least one line. The stepped portions ST and ST′ of the plurality of data link lines DLK may be arranged along, for example, two different lines.

A spacing between the stepped portions of the plurality of data link lines DLK may be greater than a spacing between the straight portions of the plurality of data link lines DLK. In this regard, the straight portion of the data link line DLK means a portion other than the stepped portion. The straight portion and the stepped portion of the data link line DLK may extend in different directions.

Referring to FIG. 4, each of some of the plurality of data link lines DLK passing through the area between the first power supply line VDL and the second power supply line VSL may be bent a plurality of times in the area between the first extension portion VDL1 of the first power supply line VDL and the first extension portion VSL1 of the second power supply line VSL so as to have at least one stepped portion ST. The stepped portions ST of the data link lines DLK positioned in the area between the first extension portion VDL1 of the first power supply line VDL and the first extension portion VSL1 of the second power supply line VSL may be arranged along a first line L1 defining a first acute angle in a clockwise direction relative to the first direction (e.g., the X-axis direction).

A spacing d3 between the stepped portions ST of the plurality of data link lines DLK may be greater than a spacing d4 between the straight portions of the plurality of data link lines DLK. The extending direction of the stepped portions ST of the plurality of data link lines DLK may define an acute angle in a counterclockwise direction with respect to the extending direction of the straight portions of the plurality of data link lines DLK. For example, the extending direction of the stepped portions ST of the plurality of data link lines DLK may be the second direction (e.g., the Y-axis direction) or may be substantially the second direction (e.g., the Y-axis direction).

Referring to FIG. 6, each of the others of the plurality of data link lines DLK being disposed in and extending across the area between the first power supply line VDL and the second power supply line VSL may be bent a plurality of times in the area between the second extension portion VDL2 of the first power supply line VDL and the second extension portion VSL2 of the second power supply line VSL so as to have at least one stepped portion ST′. The stepped portions ST′ of the data link lines DLK located in the area between the second extension portion VDL2 of the first power supply line VDL and the second extension portion VSL2 of the second power supply line VSL may be arranged along a second line L2 that defines a second acute angle greater than the first acute angle in the counterclockwise direction relative to the first direction (e.g., the X-axis direction).

A spacing d5 between the stepped portions ST′ of the plurality of data link lines DLK may be greater than a spacing d6 between the straight portions of the plurality of data link lines DLK.

The spacing d3 between the stepped portions ST of the plurality of data link lines DLK located in the area between the first extension portion VDL1 of the first power supply line VDL and the first extension portion VSL1 of the second power supply line VSL may be greater than the spacing d5 between the stepped portions ST′ of the plurality of data link lines DLK located in the area between the second extension portion VDL2 of the first power supply line VDL and the second extension portion VSL2 of the second power supply line VSL.

The extending direction of the stepped portions ST′ of the plurality of data link lines DLK may be different from the extending direction of the stepped portions ST of the plurality of data link lines DLK. The extending direction of the stepped portions ST′ of the plurality of data link lines DLK may define an acute angle in the clockwise direction relative to the extending direction of the straight portions of the plurality of data link lines DLK. For example, the direction in which the stepped portions ST of the plurality of data link lines DLK extend may form an acute angle in the clockwise direction with respect to the first direction (e.g., the X-axis direction).

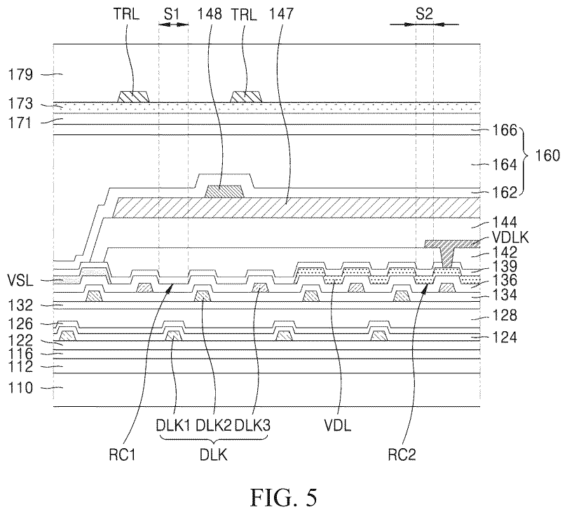

### FIG. 5 is a cross-sectional view of the display device taken along a line V-V of FIG. 4.

Referring to FIG. 5, the first and second lower buffer layers 112 and 116 and the first gate insulating layer 122 may be disposed on the substrate 110 in the link area LA of the non-display area NAA. The first data link lines DLK1 may be disposed on the first gate insulating layer 122. The first data link lines DLK1 may be made of the same material as that of the first gate electrode 123 while the first data link lines DLK1 and the first gate electrode 123 may be formed simultaneously.

The first interlayer insulating layer 124 may be disposed on the first gate insulating layer 122 so as to cover the first data link lines DLK1.

The second interlayer insulating layer 126, the upper buffer layer 128, and the second gate insulating layer 132 may be sequentially stacked on the first interlayer insulating layer 124.

The second data link lines DLK2 may be disposed on the second gate insulating layer 132. The second data link lines DLK2 may not overlap the first data link lines DLK1 in a direction perpendicular to the top surface of the substrate 110. The second data link lines DLK2 may be shifted from the first data link lines DLK1 by a predetermined distance in a direction horizontal to the upper surface of the substrate 110. In addition, the lower electrode 137 of the capacitor Cst may be disposed on the second gate insulating layer 132. The second data link lines DLK2 and the lower electrode 137 may be made of the same material as that of the second gate electrode 133, while the second data link lines DLK2, the lower electrode 137, and the second gate electrode 133 may be formed simultaneously.

The third interlayer insulating layer 134 may be disposed on the second gate insulating layer 132 so as to cover the second data link lines DLK2. The third interlayer insulating layer 134 may be made of an inorganic insulating material, and may have concave-convex patterns along surfaces of the second data link lines DLK2 and the second gate insulating layer 132.

The third data link lines DLK3 may be disposed on the second gate insulating layer 132. The third data link lines DLK3 may not overlap the first data link lines DLK1 and the second data link lines DLK2 in a direction perpendicular to the upper surface of the substrate 110. The third data link lines DLK3 may be shifted from the second data link lines DLK2 by a predetermined distance in a direction horizontal to the upper surface of the substrate 110. The third data link lines DLK3 may be made of the same material as that of the second gate electrode 133 while the third data link lines DLK3 and the second gate electrode 133 may be formed simultaneously.

The fourth interlayer insulating layer 136 may be disposed on the third interlayer insulating layer 134 so as to cover the third data link lines DLK3. The fourth interlayer insulating layer 136 may be made of an inorganic insulating material, and may have concave-convex patterns along surfaces of the third data link lines DLK3 and the third interlayer insulating layer 134.

Concave portions RC1 and RC2 may be formed in the fourth interlayer insulating layer 136 in the areas between the second data link lines DLK2 and the third data link lines DLK3.

The first power supply line VDL and the second power supply line VSL may be disposed on the fourth interlayer insulating layer 136. The first power supply line VDL and the second power supply line VSL may be spaced apart from each other.

A spacing between the stepped portions ST (see FIG. 4) of the plurality of data link lines DLK disposed in the area between the first power supply line VDL and the second power supply line VSL may be greater than a spacing between the straight portions of the plurality of data link lines DLK disposed in the area in which the plurality of data link lines DLK overlap the first power supply line VDL or the second power supply line VSL. For example, a spacing between the stepped portions ST of the second and third data link lines DLK2 and DLK3 disposed in the area between the first power supply line VDL and the second power supply line VSL may be greater than a spacing between the straight portions of the second and third data link lines DLK2 and DLK3 disposed in the area in which the second and third data link lines DLK2 and DLK3 overlap the first power supply line VDL or the second power supply line VSL. For example, the stepped portions ST of the plurality of data link lines DLK may be arranged along the first line L1 illustrated in FIG. 4.

Accordingly, a width S1 of each of the first concave portions RC1 of the fourth interlayer insulating layer 136 formed between the stepped portions ST of the second data link lines DLK2 and the third data link lines DLK3 in the area between the first power supply line VDL and the second power supply line VSL may be greater than a width S2 of each of the second concave portions RC2 of the fourth interlayer insulating layer 136 formed between the straight portions of the second data link lines DLK2 and the third data link lines DLK3 in the area in which the second data link lines DLK2 and the third data link lines DLK3 overlap the first power supply line VDL or the second power supply line VSL. The first concave portions RC1 may be arranged along at least one line. For example, the first concave portions RC1 may be arranged along the first line L1 illustrated in FIG. 4.

The passivation layer 139 covering the first power supply line VDL and the second power supply line VSL may be disposed on the fourth interlayer insulating layer 136.

The first planarization layer 142 may be disposed on the passivation layer 139. An end of the first planarization layer 142 may overlap an end of the second power supply line VSL.

The power link lines VDLK may be disposed on the first planarization layer 142. The power link lines VDLK may be connected to the first power supply line VDL via respective through-holes extending through the first planarization layer 142.

The second planarization layer 144 may cover the power link lines VDLK and may be disposed on the first planarization layer 142. An end of the second planarization layer 144 may cover an end of the first planarization layer 142 and may overlap an end of the second power supply line VSL.

The bank layer 147 and the spacer 148 may be disposed on the second planarization layer 144. The encapsulation layer 160 may be disposed on the second planarization layer 144. The encapsulation layer 160 may cover an end of the second planarization layer 144.

The touch buffer layer 171, the touch insulating layer 173, a touch routing line TRL, and the touch protection layer 179 may be disposed on the encapsulation layer 160. Each touch routing line TRL may be connected to the first touch electrode TE1 or the second touch electrode TE2. The touch routing line TRL may be connected to the pad array area PDA of the pad area PA via the connection line CL. The touch routing line TRL may be simultaneously formed with and be made of the same material as that of each of the first touch electrode TE1 and the second touch electrode TE2.

In order to form the first power supply line VDL and the second power supply line VSL described above, a metal material is deposited on the fourth interlayer insulating layer 136, and then a patterning process is performed thereon in a dry etching process. In this case, when the widths of the concave portions of the fourth interlayer insulating layer 136 formed between the plurality of data link lines DLK, specifically between the second data link lines DLK2 and the third data link lines DLK3 are small, a residual film made of a metal material that is not removed in the dry etching process may remain in the concave portions of the fourth interlayer insulating layer 136. Due to these residual films, a short-circuit may occur between the first power supply line VDL and the second power supply line VSL, and thus an operation failure of the display device may occur.

According to an implementation of the present disclosure, the width S1 of each of the first concave portions RC1 of the fourth interlayer insulating layer 136 formed between the stepped portions ST of the plurality of data link lines DLK, specifically between the stepped portions ST (see FIG. 4) of the second data link lines DLK2 and the third data link lines DLK3 in the area between the first power supply line VDL and the second power supply line VSL may be increased. Thus, in the patterning process for forming the first power supply line VDL and the second power supply line VSL, the metal material in the first concave portions RC1 of the fourth interlayer insulating layer 136 may be easily removed, and thus, the residual film may not be produced.

In addition, the stepped portions ST of the plurality of data link lines DLK are arranged along one line in the area between the first power supply line VDL and the second power supply line VSL. Thus, even when the residual film is produced in other areas except for the first concave portions RC1 of the fourth interlayer insulating layer 136, the residual film may be prevented from extending continuously in the area between the first power supply line VDL and the second power supply line VSL.

Accordingly, the short-circuit between the first power supply line VDL and the second power supply line VSL due to the residual film of the metal material between the plurality of data link lines DLK may be prevented from occurring.

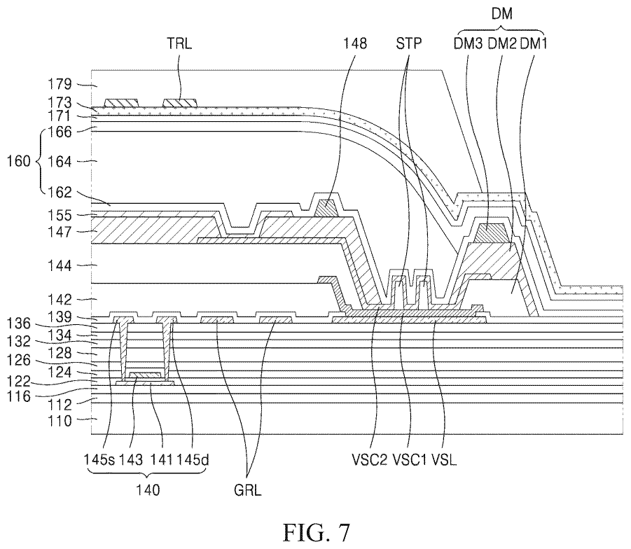

FIG. 7 is a cross-sectional view of the display device taken along a line VII-VII of FIG. 1.

Referring to FIG. 7, the display device may include a third thin-film transistor 140 disposed in the non-display area NAA of the substrate 110, a gate routing line GRL, a second power supply line VSL, a touch routing line TRL, and a dam structure DM.

The first lower buffer layer 112 and the second lower buffer layer 116 may be sequentially stacked on the substrate 110.

The third thin-film transistor 140 may be disposed on the second lower buffer layer 116. The third thin-film transistor 140 may be a component of the gate driver GD (see FIG. 1). The third thin-film transistor 140 may include a third semiconductor pattern 141, a third gate electrode 143, a third source electrode 145s, and a third drain electrode 145d. The third semiconductor pattern 141 may be disposed on the second lower buffer layer 116.

The third semiconductor pattern 141 may include a semiconductor material. For example, the third semiconductor pattern 141 may include a polycrystalline semiconductor material or an oxide semiconductor material.

The first gate insulating layer 122 may be disposed on the third semiconductor pattern 141. The first gate insulating layer 122 may cover the third semiconductor pattern 141 and may extend along an upper surface of the second lower buffer layer 116.

The third gate electrode 143 may be disposed on the first gate insulating layer 122. The third gate electrode 143 may include a conductive material. For example, the third gate electrode 143 may include a metal material such as aluminum (Al), chromium (Cr), copper (Cu), titanium (Ti), molybdenum (Mo), and tungsten (W). The third gate electrode 143 may be electrically insulated from the third semiconductor pattern 141 via the first gate insulating layer 122.

The first interlayer insulating layer 124 may be disposed on the third gate electrode 143. The first interlayer insulating layer 124 may cover the third gate electrode 143 and may extend along an upper surface of the first gate insulating layer 122.

The second interlayer insulating layer 126, the upper buffer layer 128, the second gate insulating layer 132, the third interlayer insulating layer 134, and the fourth interlayer insulating layer 136 may be sequentially stacked on the first interlayer insulating layer 124.

The third source electrode 145s and the third drain electrode 145d may be disposed on the fourth interlayer insulating layer 136. Each of the third source electrode 145s and the third drain electrode 145d may include a conductive material. For example, each of the third source electrode 145s and the third drain electrode 145d may include a metal material such as aluminum (Al), chromium (Cr), copper (Cu), titanium (Ti), molybdenum (Mo), and tungsten (W). For example, each of the third source electrode 145s and the third drain electrode 145d may include a material different from that of the third gate electrode 143. For example, each of the third source electrode 145s and the third drain electrode 145d may have a multi-layered structure of a titanium (Ti) layer/an aluminum (Al) layer/a titanium (Ti) layer.

The third source electrode 145s and the third drain electrode 145d may be electrically respectively connected to a source area and a drain area of the third semiconductor pattern 141 via respective through-hole extending through the second interlayer insulating layer 126, the upper buffer layer 128, the second gate insulating layer 132, the third interlayer insulating layer 134, and the fourth interlayer insulating layer 136. The third source electrode 145s and the third drain electrode 145d of the third thin-film transistor 140 may be simultaneously formed with and be made of the same material as that of each of the first source electrode 125s and the first drain electrode 125d of the first thin-film transistor 120.

The gate routing line GRL may be disposed on the fourth interlayer insulating layer 136. The gate routing line GRL may be a line that transmits external power or a signal to the gate driver. The gate routing line GRL may be disposed outwardly of the third thin-film transistor 140. The second power supply line VSL may be disposed on the fourth interlayer insulating layer 136. The second power supply line VSL may be disposed outwardly of the gate routing line GRL. The gate routing line GRL and the second power supply line VSL may be simultaneously formed with and be made of the same material as that of each of the third source electrode 140s and the third drain electrode 140d of the third thin-film transistor 140.

The passivation layer 139 covering the third source electrode 145s, the third drain electrode 145d, and the gate routing line GRL may be disposed on the fourth interlayer insulating layer 136. The passivation layer 139 may include an opening defined therein exposing a portion of the second power supply line VSL.

The first planarization layer 142 covering the third thin-film transistor 140 and the gate routing line GRL may be disposed on the passivation layer 139. The first planarization layer 142 may cover an end of the second power supply line VSL and may not cover a portion of the second power supply line VSL exposed through the opening of the passivation layer 139.

A first connection electrode VSC1 may be disposed on the portion of the second power supply line VSL not covered with the passivation layer 139 and the first planarization layer 142. The first connection electrode VSC1 may cover a side surface of the first planarization layer 142 adjacent to the second power supply line VSL. The first connection electrode VSC1 may include the same material as that of the intermediate electrode 146 disposed on the display area AA of the substrate 110.

The second planarization layer 144 may be disposed on the first planarization layer 142. The second planarization layer 144 may cover an upper surface and a side surface of the first planarization layer 142. The second planarization layer 144 may cover a portion of the first connection electrode VSC1.

At least one stopper STP may be disposed on the first connection electrode VSC1. The stopper STP may limit flow of the organic encapsulation layer 164 having fluidity when the organic encapsulation layer 164 is formed. The stopper STP may include the same material as that of the second planarization layer 144.

A second connection electrode VSC2 may be disposed on the second planarization layer 144. The second connection electrode VSC2 may extend outwardly beyond an end of the second planarization layer 144 so as to cover an upper surface of the first connection electrode VSC1 and an upper surface and a side surface of the stopper STP. The second connection electrode VSC2 may include the same material as that of the anode electrode 151 of the light-emitting element 150.

The bank layer 147 may be disposed on the second planarization layer 144. The bank layer 147 may include an opening defined therein exposing a portion of the second connection electrode VSC2. An end of the bank layer 147 may be positioned between an end of the second planarization layer 144 and the stopper STP.

The cathode electrode 155 of the light-emitting element 150 may be disposed on the bank layer 147 and may be connected to the portion of the second connection electrode VSC2 exposed through the opening of the bank layer 147. Accordingly, the second voltage as the low potential voltage may be applied to the cathode electrode 155 of the light-emitting element 150.

The spacer 148 may be disposed adjacent to the stopper STP and on the bank layer 147. The spacer 148 disposed on an edge of the bank layer 147 of the non-display area NAA may limit the flow of the organic encapsulation layer 164 having fluidity when the organic encapsulation layer 164 is formed.

The dam structure DM having a predetermined width may be disposed on the passivation layer 139 and at an edge of the non-display area NAA of the substrate 110. The dam structure DM may include a plurality of dam layers DM1, DM2, and DM3. For example, the dam structure DM may include a first dam layer DM1 disposed on the passivation layer 139, a second dam layer DM2 covering an upper surface and side surfaces of the first dam layer DM1, and a third dam layer DM3 disposed on an upper surface of the second dam layer DM2. The first dam layer DM1 may cover a portion of the first connection electrode VSC1. For example, the first dam layer DM1 may include the same material as that of the second planarization layer 144. For example, the second dam layer DM2 may include the same material as that of the bank layer 147. For example, the third dam layer DM3 may include the same material as that of the spacer 148. The dam structure DM may include the first to third dam layers DM1, DM2, and DM3. However, implementations of the present disclosure are not limited thereto. In another implementation, the dam structure DM may further include an additional dam layer including the same material as that of the first planarization layer 142 and disposed under the first dam layer DM1.

The encapsulation layer 160 may be located on the cathode electrode 155. The encapsulation layer 160 may include the first inorganic encapsulation layer 162, the organic encapsulation layer 164, and the second inorganic encapsulation layer 166, which are sequentially stacked. The first inorganic encapsulation layer 162 may cover the cathode electrode 155 of the light-emitting element 150, the spacer 148, the stopper STP, and the dam structure DM. The dam structure DM together with the stopper STP may limit the flow of the organic encapsulation layer 164 having fluidity when the organic encapsulation layer 164 is formed. For example, an end of the organic encapsulation layer 164 may be located on the inner side surface of the dam structure DM. The second inorganic encapsulation layer 166 may cover the organic encapsulation layer 164 and the first inorganic encapsulation layer 162.

The touch buffer layer 171, the touch insulating layer 173, the touch routing line TRL, and the touch protection layer 179 may be disposed on the encapsulation layer 160. Each touch routing line TRL may be connected to the first touch electrode TE1 or the second touch electrode TE2. For example, the touch buffer layer 171 may cover the second inorganic encapsulation layer 166. For example, the touch insulating layer 173 may cover the touch buffer layer 171. For example, the touch routing line TRL may be disposed on the third thin-film transistor 140 and the gate routing line GRL. For example, an end of the touch protection layer 179 may be located on the dam structure DM.

The display device according to various aspects and implementations of the present disclosure may be described as follows.

A first aspect of the present disclosure provides a display device comprising: a substrate including a display area and a link area disposed on one side of the display area; a plurality of data link lines disposed on the link area and connected to a plurality of data lines disposed on the display area; and a first power supply line and a second power supply line disposed on the link area and intersecting the plurality of data link lines, wherein the first power supply line and the second power supply line are spaced apart from each other, wherein in a plan view of the display device, each of the plurality of data link lines is partially disposed in and extends along an area between the first power supply line and the second power supply line, wherein in the plan view, each of the plurality of data link lines is bent a plurality of times in the area between the first power supply line and the second power supply line so as to have at least one stepped portion in the area.

In accordance with some implementations of the first aspect of the present disclosure, a spacing between the stepped portions of the plurality of data link lines is greater than a spacing between straight portions of the plurality of data link lines.

In accordance with some implementations of the first aspect of the present disclosure, the stepped portions of the plurality of data link lines are arranged along at least one line.

In accordance with some implementations of the first aspect of the present disclosure, the first power supply line includes a first extension portion extending in a first direction and a second extension portion extending in a second direction different from the first direction, wherein the second power supply line includes a first extension portion extending in the first direction and a second extension portion extending in the second direction, wherein each of some of the plurality of data link lines has at least one stepped portion in an area between the first extension portion of the first power supply line and the first extension portion of the second power supply line, wherein each of the others of the plurality of data link lines has at least one stepped portion in an area between the second extension of the first power supply line and the second extension of the second power supply line.

In accordance with some implementations of the first aspect of the present disclosure, the stepped portions positioned in the area between the first extension portion of the first power supply line and the first extension portion of the second power supply line are arranged along a first line, wherein the stepped portions positioned in the area between the second extension portion of the first power supply line and the second extension portion of the second power supply line are arranged along a second line different from the first line.

In accordance with some implementations of the first aspect of the present disclosure, a first spacing between the stepped portions positioned in the area between the first extension portion of the first power supply line and the first extension portion of the second power supply line is greater than a second spacing between the stepped portions positioned in the area between the second extension portion of the first power supply line and the second extension portion of the second power supply line.

In accordance with some implementations of the first aspect of the present disclosure, an extending direction of each of the stepped portions positioned in the area between the first extension portion of the first power supply line and the first extension portion of the second power supply line is different from an extending direction of each of the stepped portions positioned in the area between the second extension portion of the first power supply line and the second extension portion of the second power supply line.

In accordance with some implementations of the first aspect of the present disclosure, the plurality of data link lines include first, second, and third data link lines respectively disposed in different layers on the substrate, wherein the first to third data link lines do not overlap each other in a direction perpendicular to an upper surface of the substrate.

In accordance with some implementations of the first aspect of the present disclosure, each of the first data link lines is disposed in the same layer as a layer of a first gate electrode of a first thin-film transistor disposed on the display area and is made of the same material as a material of the first gate electrode of the first thin-film transistor.

In accordance with some implementations of the first aspect of the present disclosure, each of the second data link lines is disposed in the same layer as a layer of a second gate electrode of a second thin-film transistor disposed on the display area and on the first thin-film transistor and is made of the same material as a material of the second gate electrode of the second thin-film transistor.

In accordance with some implementations of the first aspect of the present disclosure, each of the third data link lines is disposed in the same layer as a layer of an upper electrode of a capacitor disposed on the display area and disposed on the second gate electrode, and is made of the same material as a material of the upper electrode of the capacitor.

In accordance with some implementations of the first aspect of the present disclosure, a vertical level of each of the third data link lines is higher than a vertical level of each of the first and second data link lines, wherein the display device further comprises an interlayer insulating layer covering the third data link lines, wherein the interlayer insulating layer includes: first concave portions, each being formed between adjacent ones of the stepped portions of the second data link lines and the third data link lines in the area between the first power supply line and the second power supply line; and second concave portions, each being formed between adjacent ones of the straight portions of the second data link lines and the third data link lines in an area in which the second data link lines and the third data link lines overlap the first power supply line or the second power supply line, wherein a width of each of the first concave portions is greater than a width of each of the second concave portions.

A second aspect of the present disclosure provides a display device comprising: a substrate including a display area and a link area disposed on one side of the display area; first, second, and third data link lines disposed on the link area and respectively positioned in different layers, wherein the first, second, and third data link lines do not overlap each other in a direction perpendicular to an upper surface of the substrate, wherein a vertical level of each of the third data link lines is higher than a vertical level of each of the first and second data link lines; an interlayer insulating layer covering the third data link lines; and a first power supply line and a second power supply line disposed on the link area and on the interlayer insulating layer and intersecting the first to third data link lines, wherein the first power supply line and the second power supply line are spaced apart from each other, wherein each of the first to third data link lines is bent a plurality of times in an area between the first power supply line and the second power supply line so as to have at least one stepped portion in the area, wherein the interlayer insulating layer includes first concave portions, wherein each of the first concave portions is formed between adjacent ones of the stepped portions of the second data link lines and the third data link lines in the area between the first power supply line and the second power supply line, wherein the first concave portions are arranged along at least one line.

In accordance with some implementations of the second aspect of the present disclosure, the interlayer insulating layer further includes second concave portions, wherein each of the second concave portions is formed between adjacent ones of straight portions of the second data link lines and the third data link lines in an area in which the second data link lines and the third data link lines overlap the first power supply line or the second power supply line, wherein a width of each of the first concave portions is greater than a width of each of the second concave portions.

In accordance with some implementations of the second aspect of the present disclosure, a spacing between the stepped portions of the first to third data link lines is greater than a spacing between the straight portions of the first to third data link lines.

In accordance with some implementations of the second aspect of the present disclosure, the stepped portions of the first to third data link lines are arranged along at least one line.

Although some implementations of the present disclosure have been described above with reference to the accompanying drawings, the present disclosure may not be limited to some implementations and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some implementations as described above are not restrictive but illustrative in all respects.

What is claimed is:

1. A display device comprising:
a substrate including a display area and a link area disposed on one side of the display area;
a plurality of data link lines disposed on the link area and connected to a plurality of data lines disposed on the display area; and
a first power supply line and a second power supply line disposed on the link area and intersecting the plurality of data link lines, wherein the first power supply line and the second power supply line are spaced apart from each other,
wherein in a plan view of the display device, each of the plurality of data link lines is partially disposed in and extends along an area between the first power supply line and the second power supply line, and
wherein in the plan view, each of the plurality of data link lines comprises at least one stepped portion having a plurality of bends in the area between the first power supply line and the second power supply line.

2. The display device of claim 1, wherein for adjacent data link lines among the plurality of data link lines, a spacing between the at least one stepped portion of one of the adjacent data link lines and the at least one stepped portion of another of the adjacent data link lines is greater than a spacing between straight portions of the adjacent data link lines.

3. The display device of claim 1, wherein stepped portions of the plurality of data link lines, comprising the at least one stepped portion for each of the plurality of data link lines, are collectively arranged along at least one line.

4. The display device of claim 1, wherein the first power supply line includes a first extension portion extending in a first direction and a second extension portion extending in a second direction different from the first direction,
wherein the second power supply line includes a first extension portion extending in the first direction and a second extension portion extending in the second direction,
wherein each of some of the plurality of data link lines has the at least one stepped portion in an area between the first extension portion of the first power supply line and the first extension portion of the second power supply line,
wherein each of others of the plurality of data link lines has the at least one stepped portion in an area between the second extension portion of the first power supply line and the second extension portion of the second power supply line.

5. The display device of claim 4, wherein stepped portions of the some of the plurality of data link lines comprising the at least one stepped portion positioned in the area between the first extension portion of the first power supply line and the first extension portion of the second power supply line are collectively arranged along a first line,
wherein stepped portions of the others of the plurality of data link lines comprising the at least one stepped portion positioned in the area between the second extension portion of the first power supply line and the second extension portion of the second power supply line are collectively arranged along a second line different from the first line.

6. The display device of claim 4, wherein a first spacing between stepped portions of the some of the plurality of data link lines comprising the at least one stepped portion positioned in the area between the first extension portion of the first power supply line and the first extension portion of the second power supply line is greater than a second spacing between stepped portions of the others of the plurality of data link lines comprising the at least one stepped portion positioned in the area between the second extension portion of the first power supply line and the second extension portion of the second power supply line.

7. The display device of claim 4, wherein an extending direction of each of the at least one stepped portion positioned in the area between the first extension portion of the first power supply line and the first extension portion of the second power supply line is different from an extending direction of each of the at least one stepped portion positioned in the area between the second extension portion of the first power supply line and the second extension portion of the second power supply line.

8. The display device of claim 1, wherein the plurality of data link lines include first data link lines, second data link lines, and third data link lines respectively disposed in different layers on the substrate,
wherein the first data link lines, the second data link lines, and the third data link lines do not overlap each other in a direction perpendicular to an upper surface of the substrate.

9. The display device of claim 8, wherein each of the first data link lines is disposed in the same layer as a layer of a first gate electrode of a first thin-film transistor disposed on the display area and is made of the same material as a material of the first gate electrode of the first thin-film transistor.

10. The display device of claim 9, wherein each of the second data link lines is disposed in the same layer as a layer of a second gate electrode of a second thin-film transistor disposed on the display area and on the first thin-film transistor and is made of the same material as a material of the second gate electrode of the second thin-film transistor.

11. The display device of claim 10, wherein each of the third data link lines is disposed in the same layer as a layer of an upper electrode of a capacitor disposed on the display area and disposed on the second gate electrode, and is made of the same material as a material of the upper electrode of the capacitor.

12. The display device of claim 8, wherein a vertical level of each of the third data link lines is higher than a vertical level of each of the first data link lines and the second data link lines,
wherein the display device further comprises an interlayer insulating layer covering the third data link lines,
wherein the interlayer insulating layer includes:
first concave portions, each being formed between adjacent ones of the at least one stepped portion of the second data link lines and the third data link lines in the area between the first power supply line and the second power supply line; and
second concave portions, each being formed between adjacent ones of straight portions of the second data link lines and the third data link lines in an area in which the second data link lines and the third data link lines overlap the first power supply line or the second power supply line,
wherein a width of each of the first concave portions is greater than a width of each of the second concave portions.

13. A display device comprising:
a substrate including a display area and a link area disposed on one side of the display area;
first data link lines, second data link lines, and third data link lines disposed on the link area and respectively positioned in different layers, wherein the first data link lines, the second data link lines, and the third data link lines do not overlap each other in a direction perpendicular to an upper surface of the substrate, wherein a vertical level of each of the third data link lines is higher than a vertical level of each of the first data link lines and the second data link lines;
an interlayer insulating layer covering the third data link lines; and
a first power supply line and a second power supply line disposed on the link area and on the interlayer insulating layer and intersecting the first data link lines, the second data link lines, and the third data link lines, wherein the first power supply line and the second power supply line are spaced apart from each other,
wherein each of the first data link lines, the second data link lines, and the third data link lines comprises at least one stepped portion having a plurality of bends in an area between the first power supply line and the second power supply line,
wherein the interlayer insulating layer includes first concave portions, wherein each of the first concave portions is formed between adjacent ones of the at least one stepped portion of the second data link lines and the third data link lines in the area between the first power supply line and the second power supply line, and
wherein the first concave portions are arranged along at least one line.

14. The display device of claim 13, wherein the interlayer insulating layer further includes second concave portions, wherein each of the second concave portions is formed between adjacent ones of straight portions of the second data link lines and the third data link lines in an area in which the second data link lines and the third data link lines overlap the first power supply line or the second power supply line,
wherein a width of each of the first concave portions is greater than a width of each of the second concave portions.

15. The display device of claim 13, wherein a spacing between the at least one stepped portion of the first data link lines, the second data link lines, and the third data link lines is greater than a spacing between straight portions of the first data link lines, the second data link lines, and the third data link lines.

16. The display device of claim 13, wherein stepped portions comprising the at least one stepped portion of the first data link lines, the second data link lines, and the third data link lines are collectively arranged along at least one line.
